(19) United States
(12) Patent Application Publication
(10) Pub. No.: US 2025/0224464 A1
(43) Pub. Date: Jul. 10, 2025

(54) MAGNETIC FIELD DETECTION DEVICE AND MAGNETIC FIELD DETECTION METHOD

(71) Applicant: KABUSHIKI KAISHA TOSHIBA, Tokyo (JP)

(72) Inventors: Yoshihiro HIGASHI, Komatsu Ishikawa (JP); Akira KIKITSU, Yokohama Kanagawa (JP); Satoshi SHIROTORI, Yokohama Kanagawa (JP); Kenichiro YAMADA, Minato Tokyo (JP)

(73) Assignee: KABUSHIKI KAISHA TOSHIBA, Tokyo (JP)

(21) Appl. No.: 18/999,374

(22) Filed: Dec. 23, 2024

(30) Foreign Application Priority Data
Jan. 4, 2024 (JP) 2024-000321

(51) Int. Cl. G01R 33/10; G01R 33/00

(52) U.S. Cl. CPC G01R 33/10; G01R 33/0023

(57) ABSTRACT

According to one embodiment, a magnetic field detection device includes an acquisitor configured to acquire data being two-dimensional relating to a magnetic field from a detection target, and a processor configured to perform a first operation of processing the data acquired by the acquisitor. The data includes a first magnetic field distribution along a first plane, a second magnetic field distribution along a second plane parallel to the first plane, and a third magnetic field distribution along a third plane parallel to the first plane. In the first operation, the processor is configured to derive a first derived magnetic field distribution in a first derived plane parallel to the first plane based on the first magnetic field distribution, the second magnetic field distribution, and the third magnetic field distribution.

### CROSS-REFERENCE TO RELATED APPLICATIONS

This application is based upon and claims the benefit of priority from Japanese Patent Application No. 2024-000321, filed on Jan. 4, 2024; the entire contents of which are incorporated herein by reference.

### FIELD

Embodiments described herein relate generally to a magnetic field detection device and a magnetic field detection method.

### BACKGROUND

For example, an evaluation target is evaluated by detecting a magnetic field generated from the evaluation target such as an electric circuit. Higher accurate detection is desired.

### BRIEF DESCRIPTION OF THE DRAWINGS

FIG. 1 is a schematic diagram illustrating an inspection apparatus according to a first embodiment;

FIG. 2 is a schematic diagram illustrating the inspection apparatus according to the first embodiment; and

FIG. 3 is a schematic diagram illustrating the inspection device according to the first embodiment.

### DETAILED DESCRIPTION

According to one embodiment, a magnetic field detection device includes an acquisitor configured to acquire data being two-dimensional relating to a magnetic field from a detection target, and a processor configured to perform a first operation of processing the data acquired by the acquisitor. The data includes a first magnetic field distribution along a first plane, a second magnetic field distribution along a second plane parallel to the first plane, and a third magnetic field distribution along a third plane parallel to the first plane. A first distance between the detection target and the first plane in a first direction perpendicular to the first plane is shorter than a second distance between the detection target and the second plane in the first direction. The second distance is shorter than a third distance between the detection target and the third plane in the first direction. In the first operation, the processor is configured to derive a first derived magnetic field distribution in a first derived plane parallel to the first plane based on the first magnetic field distribution, the second magnetic field distribution, and the third magnetic field distribution. A first derived distance between the detection target and the first derived plane in the first direction is different from the first distance, different from the second distance, and different from the third distance.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

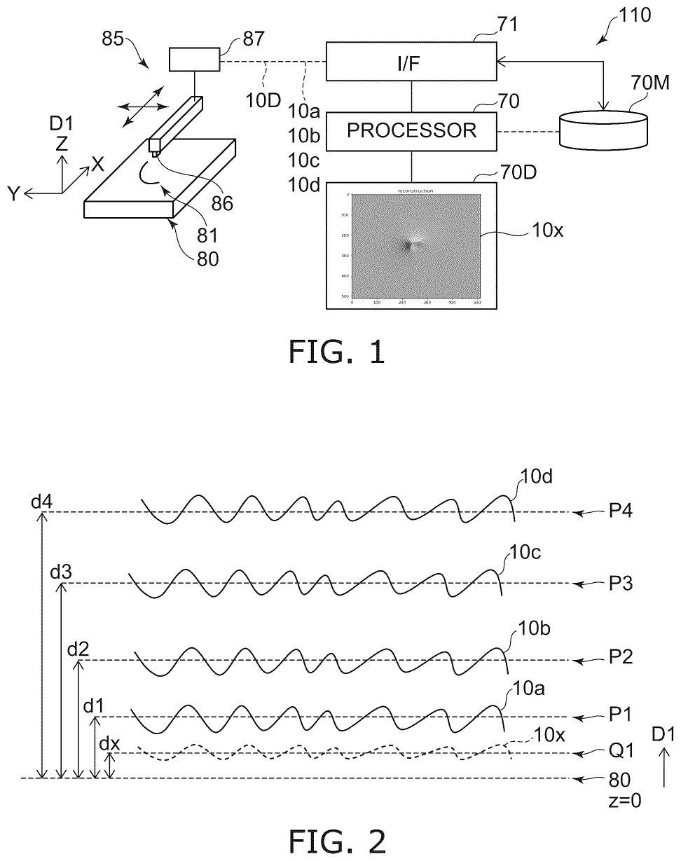

FIGS. 1 and 2 are schematic diagrams illustrating an inspection apparatus according to the first embodiment.

As shown in FIG. 1, a magnetic field detection device 110 according to the embodiment includes an acquisitor 71 and a processor 70.

The acquisitor 71 is configured to acquire data 10D being two-dimensional regarding a magnetic field from the detection target 80. The processor 70 is configured to perform a first operation of processing the data 10D acquired by the acquisitor 71. The acquisitor 71 may be an interface, for example. The processor 70 may be, for example, a processing circuitry. The processor 70 may be, for example, an electric circuit.

The data 10D may be detected by a detector 85. The detector 85 is configured to detect the data 10D being two-dimensional regarding the magnetic field from the detection target 80. The data 10D may be supplied from the detector 85 to the acquisitor 71 by any wired or wireless method. The data 10D may be stored in the storage 70M. The data 10D stored in the storage 70M may be processed by the processor 70.

In one example, the detection target 80 includes a conductive member 81 included in an electrical device. A magnetic field is generated according to current flowing through the conductive member 81. The generated magnetic field is detected by the detector 85. The detector 85 includes, for example, a sensor element 86. A distance between the detection target 80 and the sensor element 86 is variable.

A first direction D1 from the detection target 80 to the sensor element 86 is defined as a Z-axis direction. One direction perpendicular to the Z-axis direction is defined as an X-axis direction. A direction perpendicular to the Z-axis direction and the X-axis direction is defined as a Y-axis direction.

A relative positions of the sensor element 86 and the detection target 80 along a plane (X-Y plane) perpendicular to the first direction D1 are variable. For example, by changing the relative position, the sensor element 86 can detect a two-dimensional distribution of the magnetic field from the detection target 80. The two-dimensional distribution is a distribution in a plane perpendicular to the first direction D1.

The detector 85 may further include a controller 87. The change in relative position may be controlled by the controller 87. For example, the two-dimensional distribution of the magnetic field may be obtained by providing a plurality of sensor elements 86. For example, the data 10D regarding the two-dimensional distribution of the magnetic field may be supplied to the acquisitor 71 via the controller 87. The detector 85 may be included in the magnetic field detection device 110. The detector 85 may be provided separately from the magnetic field detection device 110.

The data 10D includes a first magnetic field distribution 10a, a second magnetic field distribution 10b, and a third magnetic field distribution 10c. As described later, the data 10D may further include a fourth magnetic field distribution 10d. In the first operation, the processor 70 derives a first derived magnetic field distribution 10x by processing these magnetic field distributions. The first derived magnetic field distribution 10x being derived may be displayed on the display section 70D, for example. The display section 70D and the storage 70M may be included in the magnetic field detection device 110.

FIG. 2 schematically illustrates the magnetic field distribution described above. The first magnetic field distribution 10a is along a first plane P1. The second magnetic field distribution 10b is along a second plane P2 parallel to the first plane P1. The third magnetic field distribution 10c is along a third plane P3 parallel to the first plane P1. The first plane P1 is perpendicular to the first direction D1.

A distance between the detection target 80 and the first plane P1 in the first direction D1 perpendicular to the first plane P1 is defined as a first distance d1. A distance between the detection target 80 and the second plane P2 in the first direction D1 is defined as a second distance d2. A distance between the detection target 80 and the third plane P3 in the first direction D1 is defined as a third distance d3. The first distance d1 is shorter than the second distance. The second distance d2 is shorter than the third distance d3. In this way, in the embodiment, three or more magnetic field distribution data having different distances from the detection target 80 are used.

In the first operation, the processor 70 derives the first derived magnetic field distribution 10x based on the first magnetic field distribution 10a, the second magnetic field distribution 10b, and the third magnetic field distribution 10c. The first derived magnetic field distribution 10x is a magnetic field distribution in the first derived plane Q1 parallel to the first plane P1. A first derived distance dx between the detection target 80 and the first derived plane Q1 in the first direction D1 is different from the first distance d1, different from the second distance d2, and different from the third distance d3.

The first derived distance dx is arbitrary. In the embodiment, the magnetic field distribution at an arbitrary distance (first derived distance dx) is derived with high resolution based on three or more magnetic field distribution data at 10 different positions.

In one example, the first derived distance dx is shorter than the first distance d1. For example, when an insulating film or the like is provided over the conductive member 81 (wiring) that is the detection target 80, it is difficult to make the distance between the wiring and the sensor element 86 less than the thickness of the insulating film. In such a case, based on three or more magnetic field distributions in which the distance between the wiring and the sensor element 86 is equal to or greater than the thickness of the insulating film, the magnetic field distribution at a distance less than the thickness of the insulating film can be detected with high accuracy with high resolution. According to the embodiment, a magnetic field detection device capable of highly accurate detection can be provided.

For example, the relationship between the magnetic field distribution in any plane parallel to the first plane P1 and the distance between the detection target 80 in the first direction D1 and the plane parallel to the first plane P1 is expressed by the first function of the second and third equations based on the Biot-Savart equation of the first equation below.

$$Δ H = - \frac{t}{σ} \times {j}_{e} - ∇ ( ∇ \cdot M ) \qquad ( 1 )$$

$$H ( r ) = \frac{1}{4 π} \int \frac{- {∇}^{′} \times i ( {r}^{′} ) - {∇}^{′} ( {∇}^{′} \cdot M ( {r}^{′} ) )}{r - {r}^{′}} {dr}^{′}$$

$$h ( {k}_{x} , {k}_{y} , z ) = a ( {k}_{x} , {k}_{y} ) {e}^{+ {( \sqrt{{k}_{x}^{2} + {k}_{y}^{2}} )}^{z}} + b ( {k}_{x} , {k}_{y} ) {e}^{- {( \sqrt{{k}_{x}^{2} + {k}_{y}^{2}} )}^{z}} \qquad ( 2 )$$

$${h}_{z} ( {k}_{x} , {k}_{y} ) = a ( {k}_{x} , {k}_{y} ) + b ( {k}_{x} , {k}_{y} )$$

$${h}_{z} ( {k}_{x} , {k}_{y} ) = \sqrt{{k}_{x}^{2} + {k}_{y}^{2}} \{ a ( {k}_{x} , {k}_{y} ) - b ( {k}_{x} , {k}_{y} ) \} \qquad ( 3 )$$

The second equation is a general solution of the magnetic field in the wave number space in the magnetic generation space to be measured from the magnetic sensor where no magnetic field generation source exists. “a” and “b” in the second equation are determined using the measurement data that are the Neumann boundary condition and the Dirichlet boundary condition. Thereby, it is possible to calculate the magnetic field strength at any height (position in the Z-axis direction). In the second equation, “a” is the first coefficient. “b” is the second coefficient. “z” corresponds to the distance between the detection target 80 in the first direction D1 and the plane parallel to the first plane P1. “kₓ” is the wave number in the X-axis direction, and “k_{y}” is the wave number in the Y-axis direction. In the second equation and third equation, the description in Non-Patent Document 1 (26th Spring Conference of The Japan Institute of Electronics Packaging, 8C-07, pp. 170-172.) may be applied.

The first function and second function described above are determined based on the first magnetic field distribution 10a, the second magnetic field distribution 10b, and the third magnetic field distribution 10c. As described above, in the first operation, the processor 70 derives the first derived magnetic field distribution 10x based on the first magnetic field distribution 10a, the second magnetic field distribution 10b, and the third magnetic field distribution 10c using the first function related to the magnetic field distribution in the plane parallel to the first plane P1 and the distance between the detection target 80 and the plane parallel to the first plane P1 in the first direction D1.

The above first coefficient and second coefficient can be derived from, for example, two magnetic field distributions. However, in this case, the first derived magnetic field distribution 10x is derived by linearly approximating the two magnetic field distributions. Therefore, the accuracy of the derived results is insufficient.

In the embodiment, the first derived magnetic field distribution 10x is derived using three or more magnetization distributions. In this case, derivation is possible by high-order approximation instead of linear approximation. For example, derivation that takes into account the rate of change in the magnetic field distribution in space is possible. Therefore, high accuracy can be obtained.

In the embodiment, the measurement result of the first magnetic field distribution 10a may include noise. In this case, the amplitude of this noise corresponds to a change in distance (first length) along the first direction D1. In the embodiment, a first absolute value of a first difference between the first distance d1 and the second distance d2 may be set to be longer than a first length along the first direction D1 corresponding to the first amplitude of the first noise included in the first magnetic field distribution 10a. Thus, the influence of noise can be suppressed.

In the embodiment, a second absolute value of a second difference between the second distance d2 and the third distance d3 may be set to be longer than a second length along the first direction D1 corresponding to the second amplitude of the second noise included in the second magnetic field distribution 10b.

In the embodiment, the processor 70 may further derive the first derived magnetic field distribution 10x based on a fourth magnetic field distribution 10d in the first operation. The fourth magnetic field distribution 10d may be included in the data 10D. As shown in FIG. 2, the fourth magnetic field distribution 10d is along a fourth plane P4 parallel to the first plane P1. A fourth distance d4 between the detection target 80 and the fourth plane P4 in the first direction D1 is different from the first distance d1, different from the second distance d2, different from the third distance d3, and different from the first derived distance dx. By using four or more magnetic distributions, higher accuracy is obtained.

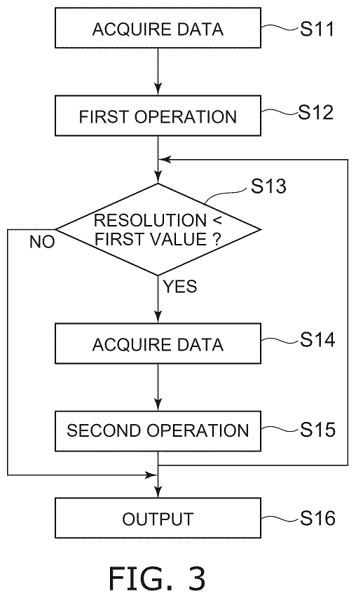

FIG. 3 is a schematic diagram illustrating the inspection device according to the first embodiment.

As shown in FIG. 3, the acquisitor 71 acquires the data 10D (step S11). For example, in the first operation, the processor 70 derives the first derived magnetic field distribution 10x based on the first magnetic field distribution 10a, the second magnetic field distribution 10b, and the third magnetic field distribution 10c (step S12).

The resolution in the first derived magnetic field distribution 10x being derived is compared with a first value (threshold) (step S13). If the resolution of the first derived magnetic field distribution 10x is lower than the first value, the processor 70 derives the first derived magnetic field distribution 10x based on the fourth magnetic field distribution 10d in the second operation (step S15). At this time, the data 10D including the fourth magnetic field distribution 10d may be further acquired between step S13 and step S15 (step S14). Alternatively, the fourth magnetic field distribution 10d may be acquired in step S11.

By deriving the first derived magnetic field distribution 10x further based on the fourth magnetic field distribution 10d, a more accurate result can be obtained. This result may be further compared with a first value (threshold) (step S13). Step S13, step S14, and step S15 may be repeated.

If the resolution is greater than or equal to the first value (threshold), the first derived magnetic field distribution 10x is output (step S16).

As already explained, the magnetic field detection device 110 may further include the detector 85 configured to detect the data 10D. For example, after the detector 85 detects the first magnetic field distribution 10a, the second magnetic field distribution 10b, and the third magnetic field distribution 10c, the processor 70 may perform the first operation described above. Then, when the resolution in the first derived magnetic field distribution 10x derived in the first operation is lower than the first value (threshold value), the detector 85 may detect the fourth magnetic field distribution 10d. For example, if the resolution is high, the fourth magnetic field distribution 10d may not be detected. The time for detecting magnetic field distribution can be shortened.

The detector 85 may detect one of the second magnetic field distribution 10b and the third magnetic field distribution 10c after detecting the first magnetic field distribution 10a. The detector 85 may detect the other one of the second magnetic field distribution 10b and the third magnetic field distribution 10c after detecting the above-mentioned one of the second magnetic field distribution 10b and the third magnetic field distribution 10c. For example, detection of the magnetic field at a position closest to the detection target 80 is performed first. This makes it easy to shorten the detection time.

### Second Embodiment

The second embodiment relates to a magnetic field detection method. The magnetic field detection method may correspond to the magnetic field distribution image derivation method.

The magnetic field detection method according to the embodiment acquires the data 10D being two-dimensional regarding the magnetic field from the detection target 80 and performs a first operation of processing the data 10D. The data 10D includes the first magnetic field distribution 10a along the first plane P1, the second magnetic field distribution 10b along the second plane P2 parallel to the first plane P1, and the third magnetic field distribution 10c along the third plane P3 parallel to the first plane P1.

The first distance d1 between the detection target 80 and the first plane P1 in the first direction D1 perpendicular to the first plane P1 is shorter than the second distance d2 between the detection target 80 and the second plane P2 in the first direction D1. The second distance d2 is shorter than a third distance d3 between the detection target 80 and the third plane P3 in the first direction D1.

In the first operation, the first derived magnetic field distribution 10x in the first derived plane Q1 parallel to the first plane P1 is derived based on the first magnetic field distribution 10a, the second magnetic field distribution 10b, and the third magnetic field distribution 10c. The first derived distance dx between the detection target 80 and the first derived plane Q1 in the first direction D1 is different from the first distance d1, different from the second distance d2, and different from the third distance d3. Thereby, a magnetic field detection method capable of highly accurate detection is provided.

For example, the first derived distance dx may be shorter than the first distance d1. For example, the first absolute value of the first difference between the first distance d1 and the second distance d2 is preferably longer than the first length along the first direction D1 corresponding to the first amplitude of the first noise included in the first magnetic field distribution 10a. The second absolute value of the second difference between the second distance d2 and the third distance d3 is preferably longer than the second length along the first direction D1 corresponding to the second amplitude of the second noise included in the second magnetic field distribution 10b.

In the first operation, the first derived magnetic field distribution 10x is derived based on the first magnetic field distribution 10a, the second magnetic field distribution 10b, and the third magnetic field distribution 10c using the first function related to the magnetic field distribution in an arbitrary plane parallel to the first plane P1 and a distance between the detection target 80 and the plane parallel to the first plane P1 in the first direction D1.

The first function includes the first coefficient and the second coefficient. The first coefficient and the second coefficient are determined based on the first magnetic field distribution 10a, the second magnetic field distribution 10b, and the third magnetic field distribution 10c.

If the resolution in the first derived magnetic field distribution 10x is lower than the first value, the second operation may be performed. In the second operation, the first derived magnetic field distribution 10x may be further derived based on the fourth magnetic field distribution 10d. The fourth magnetic field distribution 10d may be included in the data 10D. The fourth magnetic field distribution 10d is along the fourth plane P4 parallel to the first plane P1. The fourth distance d4 between the detection target 80 and the fourth plane P4 in the first direction D1 is different from the first distance d1, different from the second distance d2, different from the third distance d3, and different from the first derived distance dx.

In the magnetic field detection method according to the embodiment, the detector 85 may detect the data 10D. After the detector 85 detects the first magnetic field distribution 10a, the second magnetic field distribution 10b, and the third magnetic field distribution 10c, the first operation is performed. If the resolution of the first derived magnetic field distribution 10x derived in the first operation is lower than the first value, the fourth magnetic field distribution 10d may be detected by the detector 85.

For example, the detector 85 may detect one of the second magnetic field distribution 10b and the third magnetic field distribution 10c after detecting the first magnetic field distribution 10a. The detector 85 may detect the other of the second magnetic field distribution 10b and the third magnetic field distribution 10c after detecting the above-mentioned one of the second magnetic field distribution 10b and the third magnetic field distribution 10c. The detection target 80 may include the conductive member 81 included in an electrical device.

The embodiments may include the following Technical proposals (e.g., configurations):

### (Technical Proposal 1)

A magnetic field detection device, comprising:
an acquisitor configured to acquire data being two-dimensional relating to a magnetic field from a detection target; and
a processor configured to perform a first operation of processing the data acquired by the acquisitor,
the data including a first magnetic field distribution along a first plane, a second magnetic field distribution along a second plane parallel to the first plane, and a third magnetic field distribution along a third plane parallel to the first plane,
a first distance between the detection target and the first plane in a first direction perpendicular to the first plane being shorter than a second distance between the detection target and the second plane in the first direction,
the second distance being shorter than a third distance between the detection target and the third plane in the first direction,
in the first operation, the processor being configured to derive a first derived magnetic field distribution in a first derived plane parallel to the first plane based on the first magnetic field distribution, the second magnetic field distribution, and the third magnetic field distribution, and
a first derived distance between the detection target and the first derived plane in the first direction being different from the first distance, different from the second distance, and different from the third distance.

### (Technical Proposal 2)

The magnetic field detection device according to Technical proposal 1, wherein
the first derived distance is shorter than the first distance.

### (Technical Proposal 3)

The magnetic field detection device according to Technical proposal 1 or 2, wherein
a first absolute value of a first difference between the first distance and the second distance is longer than a first length along the first direction corresponding to a first amplitude of a first noise included in the first magnetic field distribution.

### (Technical Proposal 4)

The magnetic field detection device according to any one of Technical proposals 1-3, wherein
a second absolute value of a second difference between the second distance and the third distance is longer than a second length along the first direction corresponding to a second amplitude of a second noise included in the second magnetic field distribution.

### (Technical Proposal 5)

The magnetic field detection device according to any one of Technical proposals 1-4, wherein
in the first operation, the processor is configured to derive the first derived magnetic field distribution based on the first magnetic field distribution, the second magnetic field distribution, and the third magnetic field distribution using a first function related to a magnetic field distribution in a plane parallel to the first plane and a distance between the detection target and the plane parallel to the first plane in the first direction.

### (Technical Proposal 6)

The magnetic field detection device according to Technical proposal 5, wherein
the first function includes a first coefficient and a second coefficient, and
the first coefficient and the second coefficient are determined based on the first magnetic field distribution, the second magnetic field distribution, and the third magnetic field distribution.

### (Technical Proposal 7)

The magnetic field detection device according to any one of Technical proposals 1-6, wherein
if a resolution of the derived first derived magnetic field distribution is lower than a first value, the processor is configured to derive the first derived magnetic field distribution further based on a fourth magnetic field distribution in a second operation,
the fourth magnetic field distribution is along a fourth plane parallel to the first plane, and
a fourth distance between the detection target and the fourth plane in the first direction is different from the first distance, different from the second distance, different from the third distance, and different from the first derived distance.

### (Technical Proposal 8)

The magnetic field detection device according to Technical proposal 7, further comprising:
a detector configured to detect the data,
the processor being configured to perform the first operation after the detector detects the first magnetic field distribution, the second magnetic field distribution, and the third magnetic field distribution, and
if the resolution in the first derived magnetic field distribution derived in the first operation is lower than the first value, the detector detecting the fourth magnetic field distribution.

### (Technical Proposal 9)

The magnetic field detection device according to Technical proposal 8, wherein
the detector detects one of the second magnetic field distribution and the third magnetic field distribution after detecting the first magnetic field distribution, and
after detecting the one of the second magnetic field distribution and the third magnetic field distribution, another one of the second magnetic field distribution and the third magnetic field distribution is detected.

### (Technical Proposal 10)

The magnetic field detection device according to any one of Technical proposals 1-9, wherein
the detection target includes a conductive member included in an electric device.

### (Technical Proposal 11)

A magnetic field detection method, comprising:
acquiring data being two-dimensional relating to a magnetic field from a detection target; and
performing a first operation of processing the data,
the data including a first magnetic field distribution along a first plane, a second magnetic field distribution along a second plane parallel to the first plane, and a third magnetic field distribution along a third plane parallel to the first plane,
a first distance between the detection target and the first plane in a first direction perpendicular to the first plane being shorter than a second distance between the detection target and the second plane in the first direction,
a second distance being shorter than a third distance between the detection target and the third plane in the first direction,
in the first operation, a first derived magnetic field distribution in a first derived plane parallel to the first plane being derived based on the first magnetic field distribution, the second magnetic field distribution, and the third magnetic field distribution, and
a first derived distance between the detection target and the first derived plane in the first direction being different from the first distance, different from the second distance, and different from the third distance.

### (Technical Proposal 12)

The magnetic field detection method according to Technical proposal 11, wherein
the first derived distance is shorter than the first distance.

### (Technical Proposal 13)

The magnetic field detection method according to Technical proposal 11 or 12, wherein
a first absolute value of a first difference between the first distance and the second distance is longer than a first length along the first direction corresponding to a first amplitude of a first noise included in the first magnetic field distribution.

### (Technical Proposal 14)

The magnetic field detection method according to any one of Technical proposals 11-13, wherein
a second absolute value of a second difference between the second distance and the third distance is longer than a second length along the first direction corresponding to a second amplitude of a second noise included in the second magnetic field distribution.

### (Technical Proposal 15)

The magnetic field detection method according to any one of Technical proposals 11-14, wherein
in the first operation, the first derived magnetic field distribution is derived based on the first magnetic field distribution, the second magnetic field distribution, and the third magnetic field distribution using a first function related to a magnetic field distribution in a plane parallel to the first plane and a distance between the detection target and the plane parallel to the first plane in the first direction.

### (Technical Proposal 16)

The magnetic field detection method according to Technical proposal 15, wherein
the first function includes a first coefficient and a second coefficient, and
the first coefficient and the second coefficient are determined based on the first magnetic field distribution, the second magnetic field distribution, and the third magnetic field distribution.

### (Technical Proposal 17)

The magnetic field detection method according to any one of Technical proposals 11-16, further comprising:
performing a second operation if a resolution in the derived first derived magnetic field distribution being lower than a first value; and
in the second operation, deriving the first derived magnetic field distribution further based on a fourth magnetic field distribution,
the fourth magnetic field distribution being along a fourth plane parallel to the first plane, and
a fourth distance between the detection target and the fourth plane in the first direction being different from the first distance, different from the second distance, different from the third distance, and different from the first derived distance.

### (Technical Proposal 18)

The magnetic field detection method according to Technical proposal 17, further comprising:
detecting the data by a detector,
the first operation being performed after the detector detects the first magnetic field distribution, the second magnetic field distribution, and the third magnetic field distribution, and
the fourth magnetic field distribution being detected by the detector if the resolution in the first derived magnetic field distribution derived in the first operation is lower than the first value.

### (Technical Proposal 19)

The magnetic field detection method according to Technical proposal 18, wherein
the detector detects one of the second magnetic field distribution and the third magnetic field distribution after detecting the first magnetic field distribution, and
after detecting the one of the second magnetic field distribution and the third magnetic field distribution, another one of the second magnetic field distribution and the third magnetic field distribution is detected.

### (Technical Proposal 20)

The magnetic field detection method according to any one of Technical proposals 11-19, wherein
the detection target includes a conductive member included in an electric device.

According to the embodiment, a magnetic field detection device and a magnetic field detection method capable of highly accurate detection can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in magnetic field detection devices such as acquisitors, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all magnetic field detection devices and all magnetic field detection methods practicable by an appropriate design modification by one skilled in the art based on the magnetic field detection devices and the magnetic field detection methods described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A magnetic field detection device, comprising:
an acquisitor configured to acquire data being two-dimensional relating to a magnetic field from a detection target; and
a processor configured to perform a first operation of processing the data acquired by the acquisitor,
the data including a first magnetic field distribution along a first plane, a second magnetic field distribution along a second plane parallel to the first plane, and a third magnetic field distribution along a third plane parallel to the first plane,
a first distance between the detection target and the first plane in a first direction perpendicular to the first plane being shorter than a second distance between the detection target and the second plane in the first direction,
the second distance being shorter than a third distance between the detection target and the third plane in the first direction,
in the first operation, the processor being configured to derive a first derived magnetic field distribution in a first derived plane parallel to the first plane based on the first magnetic field distribution, the second magnetic field distribution, and the third magnetic field distribution, and
a first derived distance between the detection target and the first derived plane in the first direction being different from the first distance, different from the second distance, and different from the third distance.

2. The device according to claim 1, wherein
the first derived distance is shorter than the first distance.

3. The device according to claim 1, wherein
a first absolute value of a first difference between the first distance and the second distance is longer than a first length along the first direction corresponding to a first amplitude of a first noise included in the first magnetic field distribution.

4. The device according to claim 1, wherein
a second absolute value of a second difference between the second distance and the third distance is longer than a second length along the first direction corresponding to a second amplitude of a second noise included in the second magnetic field distribution.

5. The device according to claim 1, wherein
in the first operation, the processor is configured to derive the first derived magnetic field distribution based on the first magnetic field distribution, the second magnetic field distribution, and the third magnetic field distribution using a first function related to a magnetic field distribution in a plane parallel to the first plane and a distance between the detection target and the plane parallel to the first plane in the first direction.

6. The device according to claim 5, wherein
the first function includes a first coefficient and a second coefficient, and
the first coefficient and the second coefficient are determined based on the first magnetic field distribution, the second magnetic field distribution, and the third magnetic field distribution.

7. The device according to claim 1, wherein
if a resolution of the derived first derived magnetic field distribution is lower than a first value, the processor is configured to derive the first derived magnetic field distribution further based on a fourth magnetic field distribution in a second operation,
the fourth magnetic field distribution is along a fourth plane parallel to the first plane, and
a fourth distance between the detection target and the fourth plane in the first direction is different from the first distance, different from the second distance, different from the third distance, and different from the first derived distance.

8. The device according to claim 7, further comprising:
a detector configured to detect the data,
the processor being configured to perform the first operation after the detector detects the first magnetic field distribution, the second magnetic field distribution, and the third magnetic field distribution, and
if the resolution in the first derived magnetic field distribution derived in the first operation is lower than the first value, the detector detecting the fourth magnetic field distribution.

9. The device according to claim 8, wherein
the detector detects one of the second magnetic field distribution and the third magnetic field distribution after detecting the first magnetic field distribution, and
after detecting the one of the second magnetic field distribution and the third magnetic field distribution, another one of the second magnetic field distribution and the third magnetic field distribution is detected.

10. The device according to claim 1, wherein
the detection target includes a conductive member included in an electric device.

11. A magnetic field detection method, comprising:
acquiring data being two-dimensional relating to a magnetic field from a detection target; and
performing a first operation of processing the data,
the data including a first magnetic field distribution along a first plane, a second magnetic field distribution along a second plane parallel to the first plane, and a third magnetic field distribution along a third plane parallel to the first plane,
a first distance between the detection target and the first plane in a first direction perpendicular to the first plane being shorter than a second distance between the detection target and the second plane in the first direction,
a second distance being shorter than a third distance between the detection target and the third plane in the first direction,
in the first operation, a first derived magnetic field distribution in a first derived plane parallel to the first plane being derived based on the first magnetic field distribution, the second magnetic field distribution, and the third magnetic field distribution, and
a first derived distance between the detection target and the first derived plane in the first direction being different from the first distance, different from the second distance, and different from the third distance.

12. The method according to claim 11, wherein
the first derived distance is shorter than the first distance.

13. The method according to claim 11, wherein
a first absolute value of a first difference between the first distance and the second distance is longer than a first length along the first direction corresponding to a first amplitude of a first noise included in the first magnetic field distribution.

14. The method according to claim 11, wherein
a second absolute value of a second difference between the second distance and the third distance is longer than a second length along the first direction corresponding to a second amplitude of a second noise included in the second magnetic field distribution.

15. The method according to claim 11, wherein
in the first operation, the first derived magnetic field distribution is derived based on the first magnetic field distribution, the second magnetic field distribution, and the third magnetic field distribution using a first function related to a magnetic field distribution in a plane parallel to the first plane and a distance between the detection target and the plane parallel to the first plane in the first direction.

16. The method according to claim 15, wherein
the first function includes a first coefficient and a second coefficient, and
the first coefficient and the second coefficient are determined based on the first magnetic field distribution, the second magnetic field distribution, and the third magnetic field distribution.

17. The method according to claim 11, further comprising:
performing a second operation if a resolution in the derived first derived magnetic field distribution being lower than a first value; and
in the second operation, deriving the first derived magnetic field distribution further based on a fourth magnetic field distribution,
the fourth magnetic field distribution being along a fourth plane parallel to the first plane, and
a fourth distance between the detection target and the fourth plane in the first direction being different from the first distance, different from the second distance, different from the third distance, and different from the first derived distance.

18. The method according to claim 17, further comprising:
detecting the data by a detector,
the first operation being performed after the detector detects the first magnetic field distribution, the second magnetic field distribution, and the third magnetic field distribution, and
the fourth magnetic field distribution being detected by the detector if the resolution in the first derived magnetic field distribution derived in the first operation is lower than the first value.

19. The method according to claim 18, wherein
the detector detects one of the second magnetic field distribution and the third magnetic field distribution after detecting the first magnetic field distribution, and
after detecting the one of the second magnetic field distribution and the third magnetic field distribution, another one of the second magnetic field distribution and the third magnetic field distribution is detected.

20. The method according to claim 11, wherein
the detection target includes a conductive member included in an electric device.
